(19) United States
(12) Patent Application Publication
(10) Pub. No.: US 2024/0420761 A1
(43) Pub. Date: Dec. 19, 2024

(54) ENDURANCE, POWER, AND PERFORMANCE IMPROVEMENT LOGIC FOR A MEMORY ARRAY

(71) Applicant: NUMEM Inc., Sunnyvale, CA (US)

(72) Inventors: Jack Guedj, Los Altos Hills, CA (US); Ramamurthy Gorti, Chandler, AZ (US)

(73) Assignee: NUMEM Inc., Sunnyvale, CA (US)

(21) Appl. No.: 18/333,916

(22) Filed: Jun. 13, 2023

(51) Int. Cl. G11C 13/00; G11C 7/10

(52) U.S. Cl. CPC G11C 13/0069; G11C 7/1084; G11C 13/004

(57) ABSTRACT

Logic to provide improved endurance, performance, and power optimizing capabilities for a resistive memory, ferro-electric RAM (FeRAM) memory, or embedded flash memory is disclosed herein. In one embodiment, a memory subsystem comprises a resistive memory array; an adaptive aggregation memory buffer that has configurable settings for optimizing endurance, power, or performance of the memory subsystem; an endurance management and control logic (EMCL) coupled to the adaptive aggregation memory buffer; and an integrated processor coupled to the EMCL. At least one of the integrated processor and EMCL is configured to determine whether memory requests to a particular memory region during a time window can be aggregated into an aggregate memory request and to optimize memory settings, and to cause the aggregate memory request and memory settings to be sent to the resistive memory array, FeRAM memory, or embedded flash memory to optimize parameters including memory performance and memory endurance.

### TECHNICAL FIELD

The present disclosure relates generally to memory arrays, and more specifically to an endurance, power, and performance logic to improve endurance, power, and performance capabilities for a memory array (e.g., resistive memory array, ferro-electric RAM (FeRAM), embedded flash memory).

### BACKGROUND

Emerging memory including magnetic random access memory (MRAM, SOT MRAM, etc.), resistive RAM (RRAM, ReRAM, PC RAM) and ferro-electric RAM (FeRAM) devices are being developed as an alternative to conventional semiconductor memory devices (e.g., SRAM, DRAM, Flash) for many applications including. Internet of Things (IoT), Artificial Intelligence (AI), Consumer to Server information storage, wireless and wireline communications including mobile phones, and/or information processing including microprocessor Central Processing Unit (CPU). Embedded MRAM and resistive RAM devices provide persistent (non-volatile) storage with relatively higher densities than traditional Static Random Access Memory SRAM.

Modern portable electronic devices for IoT, wearable markets, and artificial intelligence (AI) have power consumption issues limiting battery life or impacting thermal power dissipation and datacenters are striving to lower their power footprint so looking for lower power solutions. Moreover, lack of memory density scaling imposes use of external memory which have memory access power consumption 30-60× higher than on-chip memory.

SRAM and DRAM devices are volatile memories with a need to refresh every few milliseconds, have fast read and write times (e.g., approximately 1 ns), and high endurance of greater than 10¹⁴ cycles. Emerging memory including resistive memory such as RRAM. MRAM and FeRAM as well as legacy embedded Flash memory provides non-volatile high-density memory with certain advantages but typically slower read and write times (e.g., more than 5 ns) and endurance of 10⁵ to 10¹⁰ cycles.

### SUMMARY

The systems, methods and devices of this disclosure each have several innovative aspects, no single one of which is solely responsible for the desirable attributes disclosed herein.

One innovative aspect of the subject matter described in this disclosure can be implemented as a systems, methods or memory circuitry having an optional integrated processor and logic circuitry to enable endurance, performance, and power consumption improvements for resistive memory, FeRAM, or embedded flash memory. In one embodiment, a resistive memory comprises a resistive memory array and an integrated processor combined with logic circuitry coupled to the resistive memory array. At least one of the integrated processor and logic circuitry is configured to adaptively aggregate localized memory requests to a particular memory region during a time window into an aggregate memory request and to optimize memory settings, and to cause the aggregate memory request and memory settings to be sent to the resistive memory array to optimize parameters including memory performance, memory endurance, and memory power consumption.

Details of one or more implementations of the subject matter described in this disclosure are set forth in the accompanying drawings and the description below. Other features, aspects, and advantages will become apparent from the description, the drawings and the claims. Note that the relative dimensions of the following figures may not be drawn to scale.

### BRIEF DESCRIPTION OF THE DRAWINGS

A further understanding of the nature and advantages of the present disclosure may be realized by reference to the following drawings. In the appended figures, similar components or features may have the same reference label. Further, various components of the same type may be distinguished by following the reference label by a dash and a second label that distinguishes among the similar components. If the first reference label is used in the specification, the description is applicable to any one of the similar components having the same first reference label irrespective of the second reference label.

FIG. 1 depicts a block diagram of a memory subsystem 100 with smart compute memory and an endurance, power, and performance improvement logic in accordance with one embodiment.

FIG. 2 depicts a functional block diagram of smart compute memory circuitry with smart compute memory in accordance with one embodiment.

FIG. 3 is a flow diagram illustrating a method 300 for operating a memory circuitry to improve endurance, performance, and power consumption for a computing system in accordance with one embodiment.

FIG. 4 depicts a block diagram of a memory subsystem 400 with optional smart compute memory (e.g., SoC compute-in-memory) and an endurance, power, and performance improvement logic in accordance with one embodiment.

FIG. 5 depicts a block diagram of a memory subsystem 500 with optional smart compute memory (e.g., SoC compute-in-memory) and an endurance, power, and performance improvement logic in accordance with an alternative embodiment.

FIG. 6 illustrates a block diagram of an endurance management control logic (EMCL) of a memory subsystem in accordance with one embodiment.

FIG. 7 illustrates a block diagram of an endurance management control logic (EMCL) and smart compute memory (e.g., SoC compute-in-memory) of a memory subsystem in accordance with one embodiment.

FIG. 8 shows a computer system in accordance with some embodiments described herein.

FIG. 9 illustrates a flow diagram of operational stages of an integrated processor (e.g., RISC, smart compute circuitry) in accordance with one embodiment.

### DETAILED DESCRIPTION

In the following description, numerous specific details are set forth such as examples of specific components, circuits, and processes to provide a thorough understanding of the present disclosure. The term “coupled” as used herein means connected directly to or connected through one or more intervening components or circuits. Also, in the following description and for purposes of explanation, specific nomenclature is set forth to provide a thorough understanding of the present disclosure. However, it will be apparent to one skilled in the art that these specific details may not be required to practice the example implementations. In other instances, well-known circuits and devices are shown in block diagram form to avoid obscuring the present disclosure. The present disclosure is not to be construed as limited to specific examples described herein but rather to include within their scope all implementations defined by the appended claims.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented, or a method may be practiced using any number of the aspects set forth herein. In addition, the scope of the disclosure is intended to cover such an apparatus or method, which is practiced using other structure, functionality, or structure and functionality in addition to or other than the various aspects of the disclosure set forth herein. It should be understood that any aspect of the disclosure disclosed herein may be embodied by one or more elements of a claim. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in other examples.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present application, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like. Also, “determining” may include measuring, estimating, and the like.

As used herein, the term “generating” encompasses a wide variety of actions. For example, “generating” may include calculating, causing, computing, creating, determining, processing, deriving, investigating, making, producing, providing, giving rise to, leading to, resulting in, looking up (e.g., looking up in a table, a database or another data structure), ascertaining and the like. Also, “generating” may include receiving (e.g., receiving information), accessing (e.g., accessing data in a memory) and the like. Also, “generating” may include resolving, selecting, choosing, establishing and the like.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any such list including multiples of the same members (e.g., any lists that include aa, bb, or cc).

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps are described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the claims.

Resistive RAM memory cells represent stored data as different resistance values, and are often referred to as resistive memory cells because the logic state of data stored therein may be determined by measuring the resistance value of the MRAM memory cell. Example resistive memory cells may include, but are not limited to, Magnetic RAM (MRAM) such as spin-transfer-torque (STT) memory cells, spin-orbit-torque (SOT) memory cells, resistor random access memory (ReRAM, RRAM), phase change RAM (PCRAM), voltage-controlled magnetic anisotropy (VCMA)-MRAM, and/or carbon nanotube memory cells. Aspects of the endurance, power, and performance logic of the present disclosure are applicable to resistive memory cells, ferro-electric RAM (FeRAM), and embedded non-volatile flash memory. Ferroelectric RAM is a random-access memory similar in construction to DRAM but using a ferroelectric layer instead of a dielectric layer to achieve non-volatility. A FeRAM chip contains a thin film of ferroelectric material, often lead zirconate titanate, commonly referred to as PZT. The atoms in the PZT layer change polarity in an electric field, thereby producing a power-efficient binary switch.

By way of example, STT MRAM memory cells may store different logic states of data by changing the equivalent resistance of magnetic tunnel junction (MTJ) elements. During write operations, data may be programmed into a resistive memory cell by varying a current and/or a voltage driven through the memory cell, for example, to program the resistive memory cell to either a high impedance value or a low impedance value. During read operations, a controlled current may be driven through the resistive memory cell to determine an impedance value indicative of the logic state of data stored therein.

Due to the increased data collection, it is no longer practical and power efficient to move all the data to the Cloud or across Servers. Chip size and power consumption becomes dominated by memory and memory access. Increased Non-Volatile Memory is needed to store Programs, Models/Coefficients, and an increased amount of data is collected. This is the case for example for AI/Signal Processing where AI coefficients required for Deep or Convolutional Neural Networks can exceed 1 Gigabit of memory. External Memory is a possibility for these needs but memory access power dissipation is very high for external memory (e.g., 57.5 times more power dissipation for external low power double data rate (LPDDR4) RAM memory versus internal SRAM memory). However, internal memory is area limited based on a form factor of an electronic device.

More than ever, it is critical to have efficient on chip memory for ultra-low Power dissipation and thus longer Battery Life or more efficient processing/power footprint.

Frequent off chip memory accesses and intensive power consuming devices such as a CPU operating during ON state significantly increase power consumption and reduce battery life for electronic devices. Additionally, RF circuitry also consumes significant power during normal operation of the RF circuitry.

The present design includes SoC smart compute-in-memory with a memory array (e.g., resistive RAM, FeRAM, embedded flash) to move computations and learning operations from a host system (e.g., CPU, processor, microprocessor) to SoC smart compute-in-memory in order to reduce power consumption for different types of electronic devices. SoC compute functionality inside the memory enables to conduct certain operation on the fly thereby improving both performance and overall system power. Localized processing within resistive RAM will drastically reduce overall power dissipation for electronic devices. In particular, the main SoC and its CPU will operate in a low power sleep mode more frequently instead of typically being in a full operational ON state. Memory access and data transfers will be reduced due to the in-memory SoC.

This present design also includes an endurance, power, and performance logic and an adaptive aggregation memory buffer to improve endurance, power, and performance capabilities for a memory array (e.g., resistive RAM, FeRAM, embedded flash). This present design has profound benefits in terms of improving endurance of 10× to over 100× compared to conventional endurance of resistive RAM (e.g., endurance of 10⁵ to 10¹⁰ cycles) depending on the variants of implementation for resistive memory. This improvement is important for SRAM like applications. The present design utilizes a combination of adaptive aggregation of Writes, Self-time Reads, and a Write sequence and profile for the bitcells being written.

Smart Compute Memory can also be used to augment Memory Management and Control. Programmable memory management and control enables optimizing of memory performance versus memory endurance (e.g., longer endurance time at lower energy read/write operations causing slower performance versus higher energy (e.g., higher current/voltage) read/write operations causing faster performance and lower endurance). Programmable memory management and control manages different modes for Writing/Reading to enable more usage flexibility.

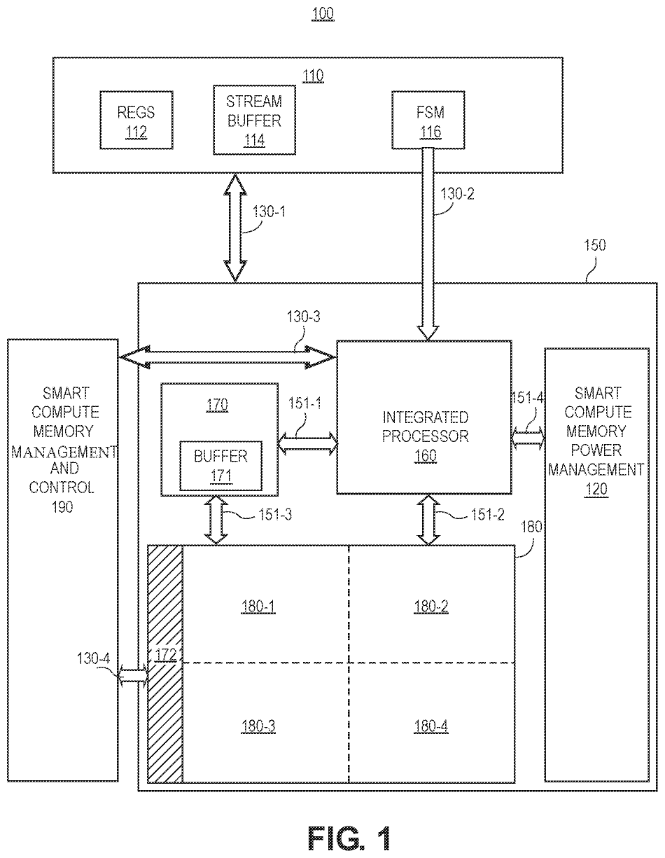

FIG. 1 depicts a block diagram of a memory subsystem 100 with optional smart compute memory (e.g., SoC compute-in-memory) and an endurance, power, and performance improvement logic in accordance with one embodiment. The memory subsystem 100 (e.g., AI subsystem, memory circuitry 100) includes an input/output (I/O) circuitry 110 having a primarily ON power state to manage input/output of data to the memory subsystem, smart compute memory power management circuitry 120, and smart compute memory circuitry 150 that includes an integrated processor 160 (e.g., processor, microprocessor, microcontroller, etc.), a smart compute memory management and control circuitry 190, endurance, power, and performance improvement logic 170 have a memory interface, an optional Adaptive Memory Management and Control circuitry (AMMC) 172, and a memory array 180 (e.g., resistive memory array 180, FeRAM array 180, embedded flash memory 180). The logic 170 can be hardware logic, logic circuitry, or program logic for performing instructions. The (I/O) circuitry 110 has the ON power state to receive external input such as streamed data.

The memory array 180 can be any type of Non-volatile resistive RAM memory (e.g., flash memory, magnetic RAM (MRAM) such as spin-transfer-torque (STT) memory cells, spin-orbit-torque (SOT) memory cells, resistive RAM (RRAM, ReRAM), phase-change RAM (PCRAM), carbon nanotube memory cells, etc.) or Ferroelectric RAM (FcRAM) for applications ranging from non-volatile RAM to low-power, high-density SRAM. Resistive RAM is non-volatile RAM computer memory that changes a resistance across a dielectric solid-state material. The dielectric layer, which is normally insulating, can become conductive through a filament or conductive path formed from application of a sufficiently high voltage. The memory array 180 has a smaller area by 2-3.5× compared to conventional RAM. In any memory application, this enables 2-3.5× more Memory On-chip to reduce off chip memory (e.g., DRAM) access for significant power savings.

This memory subsystem 100 can be a stand-alone chip or embedded as part of a larger SOC. The I/O circuitry 110 includes input stream control registers 112, a memory buffer 114 (e.g., stream FIFO buffer, queue), and a finite state machine 116 to track power states for the smart compute memory circuitry 150. Communication links 130-1, 130-2, 130-3, and 130-4 (e.g., high speed interconnects, PCIe) provide communications between the I/O circuitry 110, FSM 116, integrated processor 160, smart compute memory management and control circuitry 190, and smart compute memory circuitry 150. Interconnects connect two or more circuit elements together electrically. The integrated processor 160 can be a low power integrated processor with power-management control. The integrated processor is efficiently integrated into the memory core with integrated power management. An optional integrated processor could include but is not limited to custom logic functions (e.g., endurance, performance, power improvement logic functions), Digital Signal Processor, Reduced Instruction Set Computer (RISC) or Complex Instruction Set Computer (CISC) or a combination of custom logic functions and/or DSP including VLIW with RISC or CISC. The integrated processor can be used for memory computing or processing applications. The integrated processor can perform any software functions including add, subtract, compare and even Multiply. Similar to a CPU, the integrated processor can address a wide range of applications making Smart Compute Memory very flexible and adaptable to a wide range of applications.

In one example, the integrated processor initially fetches an instruction from memory (e.g., memory array 180, memory 1204, memory 1206). The instruction is then decoded to determine what action is to be performed. Based on instruction the integrated processor fetches, if appropriate, data from memory or an I/O module.

The instruction is then executed which may require performing arithmetic or logical operations on the data. In addition to execution, the integrated processor also supervises and controls I/O devices (e.g., I/O circuitry 110, input device 1212). If there is any request from I/O devices, called interrupt, the integrated processor suspends execution of the current programs and transfers control to an interrupt handling program. Finally, the results of an execution may require transfer of data to the memory or an I/O Module. The integrated processor is an integrated circuit (IC). The IC is a programmable multipurpose silicon chip that is clock driven, register based, and accepts binary data as input and provides output after processing it as per the instructions stored in the memory.

The integrated processor 160 can be used to augment the memory management and control of circuitry 190, AMMC 172, logic 170, and an adaptive aggregation memory buffer 171. The adaptive aggregation memory buffer 171 can be modulated based on memory type, usage pattern, or operating condition. Programmable memory management and control enables optimization of memory parameters including performance (e.g., speed) versus memory endurance (e.g., longer endurance time at lower energy read/write operations causing slower performance versus higher energy (e.g., higher current/voltage) read/write operations causing faster performance and lower endurance). Additionally, the programmable memory management and control of the integrated processor 160 enables management of different modes for writing/reading to enable more usage flexibility.

The integrated processor 160 is configured to process data (e.g., pre/post process streamed data) with results of the pre/post processing being stored in the memory array 180. Communication links 151-1, 151-2, 151-3, and 151-4 provide communications between the logic 170, integrated processor 160, power management circuitry 120, and memory array 180.

In one example, streamed data from any source (e.g., computing device, server, IoT device, sensor, etc.) is stored in a buffer (e.g., buffer 114, buffer 171). Write or Read operations for the memory array 180 are aggregated in the buffer by the logic 170 or by the processor 160 in order to improve endurance by reducing a number of write or read cycles. At periodic intervals or whenever the buffer is a threshold amount full (e.g., 25% full, 50% full, 75% full, 100% full, etc.), in one example, the logic 170 or processor 160 causes the aggregated writes to be performed as a single write operation to the memory array 180 to improve endurance, performance, and power consumption compared to handling each write operation separately. In another example, the logic 170 or processor 160 causes the aggregated reads to be performed as a single read operation from the memory array 180 to improve endurance, performance, and power consumption compared to handling each read operation separately.

The memory subsystem 100 (e.g., memory 1204) may be integrated with computer system 1200.

In one example, the FSM 116 tracks events and a threshold amount full level of the buffer 114. Upon certain events or a threshold amount full occurring in the buffer 114, then the FSM 116 provides an indicator signal to the power management circuitry 120 to change a power state of the circuitry 150. All of the components within the circuitry 150 can have a modified power state or a subset of components can have a modified power state. If the FSM 116 determines that the integrated processor 160 has processed all or most data within the buffer, then the FSM 116 can provide another indicator signal to the power management circuitry 120 to change a power state of the circuitry 150 (e.g., reduce a power state from operational to sleep state when no data to process in the buffer).

The integrated processor 160 loads its software program from main memory 1206, preprocesses the data as required, may perform a computation, and stores the result into the resistive memory array 180. During the fully operational power state, the integrated processor 160 can read data from the buffer 114, process this data or perform computations using this data, aggregate write operations based on temporal and/or spatial localization in a memory region with a single write operation into the memory array 180, aggregate reads based on temporal and/or spatial localization in a memory region with a single read operation from the memory array 180, and also receive a user query for data from the memory array 180.

In one example, the memory subsystem 100 is formed or integrated on a single chip with the host system (e.g., main CPU 1202, processor 1227). This memory subsystem 100 is configurable to a wide range of input data width (×8, ×16, ×24, . . . ), main memory size (from small sizes to in excess of 1 Gb possible), and processing options (simple integer-only to complex floating point).

In another example of the present design, the memory subsystem 100 is a stand-alone smart compute resistive RAM memory with the integrated processor 160 being used to optimize the endurance, performance, power, and test capability of the memory. The integrated processor 160 functions as Intelligent Memory Management and Control. The input data does not need to be from a sensor device; any input source is valid.

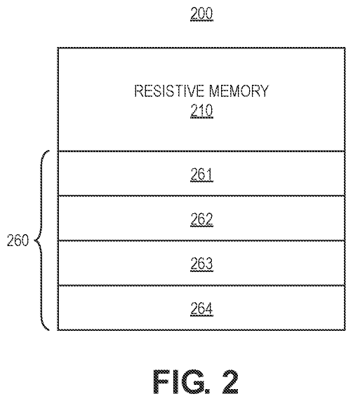

FIG. 2 depicts a functional block diagram of smart compute memory circuitry with smart compute memory in accordance with one embodiment. The smart compute memory circuitry 200 (e.g., smart compute memory circuitry 150) includes a resistive memory array 210 and a smart compute circuitry 260 (or optional integrated processor) that functions as Intelligent Memory Management and Control and endurance, power, and performance improvement logic.

In one example, the smart compute circuitry 260 includes functions that include endurance, power, and performance improvement logic 261, a data path adder/data path comparator 262, a reduction function 263, and control/storage registers 264. The functions can be pitch matched to memory input/output (e.g., I/O circuitry).

The smart compute memory circuitry 200 provides processing within the memory without waking up a host system (e.g., main CPU 1202, processor 1227) to save 10-100× in power compared to typical designs. The compute functions may include averaging, moving average, add, subtract, compare, simple multiply/divide, minimum/maximum, software applet functionality (e.g., if/then functionality), etc. If an alert is determined by the circuitry 200, then a wakeup signal can be sent to the main CPU. Design automation software customizes memory size, performance, logic functions, and data type precision.

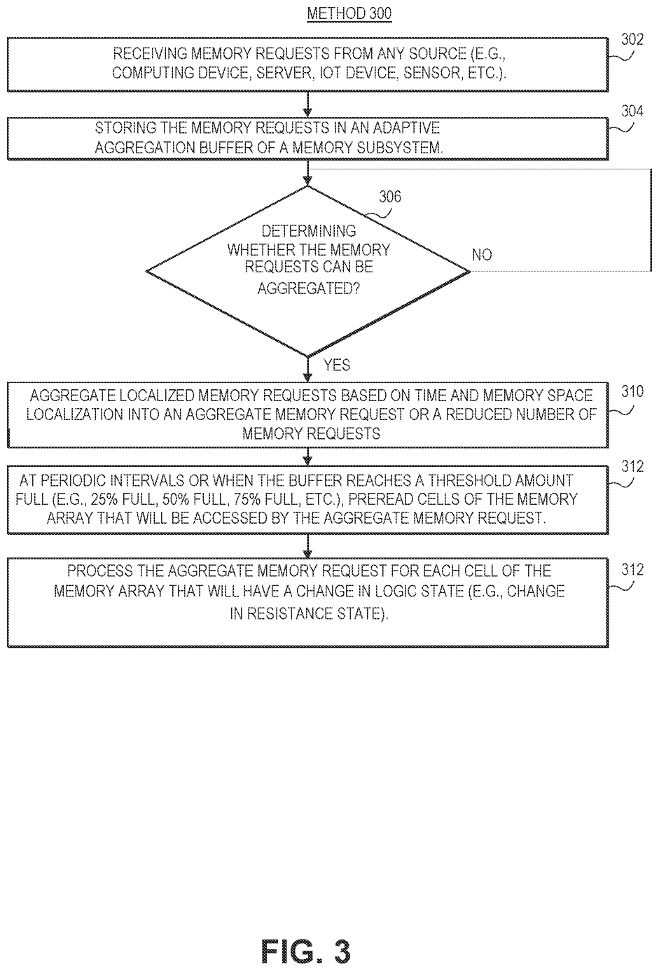

FIG. 3 is a flow diagram illustrating a method 300 for operating a memory circuitry to improve endurance, performance, and power consumption for a computing system in accordance with one embodiment. Although the operations in the method 300 are shown in a particular order, the order of the actions can be modified. Thus, the illustrated embodiments can be performed in a different order, and some operations may be performed in parallel. Some of the operations listed in FIG. 3 are optional in accordance with certain embodiments. The numbering of the operations presented is for the sake of clarity and is not intended to prescribe an order of operations in which the various operations must occur. Additionally, operations from the various flows may be utilized in a variety of combinations.

The operations of a computer-implemented method 300 may be executed by a memory subsystem, an optional smart compute memory circuitry, an optional integrated processor, or endurance management and control logic (EMCL) that configures an adaptive aggregation memory buffer. The EMCL can be logic 170, logic 440, logic 540, or EMCL 620. The memory subsystem, a smart compute memory circuitry, an integrated processor, or EMCL may include hardware (circuitry, dedicated logic, etc.), software (such as is run on a general purpose computer system or a dedicated machine or a device), or a combination of both.

At operation 302, the computer-implemented method includes receiving memory requests for a memory array from any source (e.g., computing device, server, IoT device, sensor, etc.). The optional processor or EMCL can receive the memory requests. The memory array 180 can be any type of Non-volatile resistive RAM memory (e.g., magnetic RAM (MRAM) such as spin-transfer-torque (STT) memory cells, spin-orbit-torque (SOT) memory cells, resistive RAM (RRAM, ReRAM), phase-change RAM (PCRAM), carbon nanotube memory cells, etc.), embedded flash memory, or Ferroelectric RAM (FeRAM). The memory requests (e.g., write operation, read operation, sequence of write or read operations) can be stored in an adaptive aggregation memory buffer (e.g., adaptive aggregation memory buffer 171, 630, 730) of a memory subsystem (e.g., memory subsystem 100, 400, 500, 600, 700) at operation 304. The computer-implemented method includes determining whether the memory requests can be aggregated to improve endurance, performance, and/or power consumption at operation 306 before sending the memory requests to a memory array (e.g., memory array 180, 480, 580, 680, 780).

If so, then the computer-implemented method can utilize logic (e.g., logic 170, logic 440, logic 540, or EMCL 620, 720) or an integrated processor (e.g., integrated processor 160, processor 450, processor 550, processor subsystem 710) to aggregate localized memory requests (e.g., write operations aggregated based on time and/or space localization) into a single memory request or a reduced number of memory requests at operation 310.

In one example, 15 write operations are aggregated into a single write operation for a temporal and spatial locality within a range of memory addresses (e.g., memory address X−N to memory address X to memory address X+N) or ranges of memory addresses. In another example, 100 write operations are aggregated into 10 write operations before writing to the resistive memory array for a temporal and spatial locality to perform a 90% reduction in write cycles to improve endurance, performance, and power consumption. In another example, all memory requests to a particular region are aggregated. In a similar manner, all requests during a particular time window to particular regions are aggregated.

If the memory requests are not ready for aggregation, then the method returns to operation 306 until a sufficient number of requests are buffered and ready for aggregation.

At periodic intervals or whenever the local buffer of the memory subsystem is a threshold amount full (e.g., 25% full, 50% full, 75% full, 100%, etc.), the method at operation 312 includes performing a preread of cells of the memory array that will be written to based on the aggregrate memory request. At operation 314, the aggregate memory request is processed selectively for each cell of the memory array that will have a change in logic state (e.g., change in resistance state).

In one example, a first write memory request will write to upper bits of data, a second write memory request will write to lower bits of data, and a third write memory request will write to lower and upper bits of data. In accordance with the present design, the first, second, and third memory requests are aggregated into a single memory request with write data (e.g., 11110000), and just before the aggregated memory request is processed, the method prereads memory at memory cells to be written. Only bits that are changing with a different logic state will be written to the memory array.

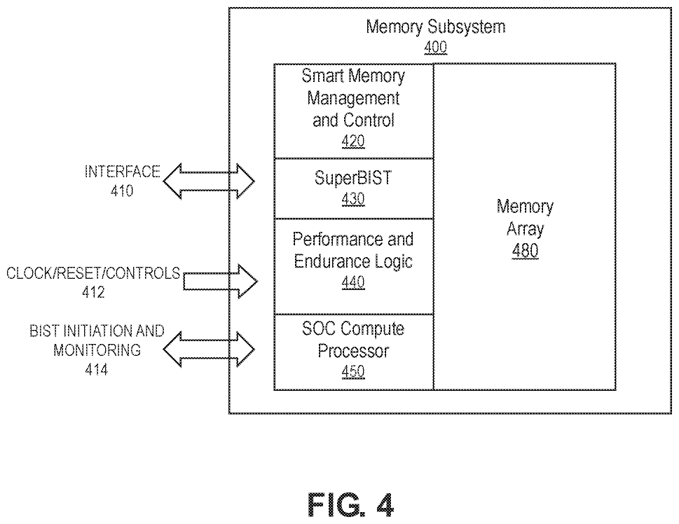

FIG. 4 depicts a block diagram of a memory subsystem 400 with an optional smart compute memory (e.g., SoC compute-in-memory) and an endurance, power, and performance improvement logic in accordance with one embodiment. The memory subsystem 400 (e.g., AI subsystem, memory circuitry 400) includes multiple interface options includes an interface 410 (e.g., parallel interface, AXI interface, HyperRAM interface, AIB, etc.), a clock, reset, and controls interface 412, and a Built-In Self Test (BIST) initiation and monitoring interface 414. BIST is a built-in testing circuitry within a software/hardware module. The test circuitry is initiated from outside of the computing system. This test circuitry, then, runs the built-in patterns/algorithms and returns a response to indicate whether the tested module is working properly.

The memory subsystem includes smart compute memory management and control circuitry 420, a SuperBist circuitry 430 to enable comprehensive and adaptive BIST, an optional integrated processor 450 (e.g., SoC compute processor, processor, microprocessor, microcontroller, etc.), and a performance and endurance logic 440. The logic 440 can be hardware logic, logic circuitry, or program logic for performing instructions. The smart compute memory management and control circuitry 420 optimizes operating profiles for optimizing power, performance, and area. In one example, the logic 440 can improve average endurance by 100× and write times by 5× compared to conventional resistive memory. The optional processor 450 provides SoC compute functionality to enable DSP and AI accelerator functions built inside the memory subsystem.

The memory array 480 can be any type of non-volatile memory (e.g., embedded flash memory, magnetic RAM (MRAM) such as spin-transfer-torque (STT) memory cells, spin-orbit-torque (SOT) memory cells, resistive RAM (RRAM, ReRAM), phase-change RAM (PCRAM), carbon nanotube memory cells, etc.) or Ferroelectric RAM (FeRAM) for applications ranging from non-volatile RAM to low-power, high-density SRAM. This memory subsystem 400 can be a stand-alone chip or embedded as part of a larger SoC.

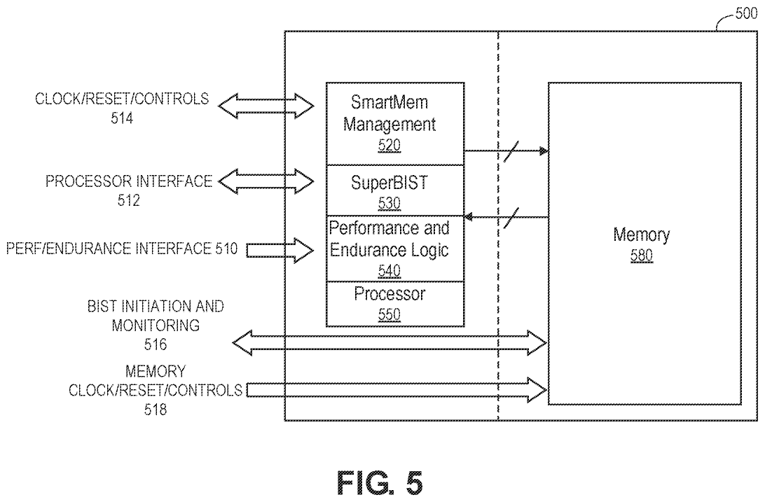

FIG. 5 depicts a block diagram of a memory subsystem 500 with an optional smart compute memory (e.g., SoC compute-in-memory) and an endurance, power, and performance improvement logic in accordance with an alternative embodiment. The memory subsystem 500 (e.g., AI subsystem, memory circuitry 500) includes multiple interface options includes an interface 510 (e.g., parallel interface, AXI interface, logic 540 interface, etc.), a processor interface 512, a clock, reset, and controls interface 514, and a Built-In Self Test (BIST) initiation and monitoring interface 516, and a memory interface 518 (e.g., memory clock, reset, controls interface).

The memory subsystem includes smart compute memory management and control circuitry 520, a SuperBist circuitry 530 to enable comprehensive and adaptive BIST, an optional integrated processor 550, and a performance, power, and endurance logic 540. The logic 540 can be hardware logic, logic circuitry, or program logic for performing instructions.

The external memory array 580 can be any type of Non-volatile memory (e.g., embedded flash memory, magnetic RAM (MRAM) such as spin-transfer-torque (STT) memory cells, spin-orbit-torque (SOT) memory cells, resistive RAM (RRAM, ReRAM), phase-change RAM (PCRAM), carbon nanotube memory cells, etc.) or Ferroelectric RAM (FeRAM) for applications ranging from non-volatile RAM to low-power, high-density SRAM. This memory array 580 can be external from the circuitry 520, circuitry 530, logic 540, and processor 550. The memory array 580 can include error correction code (ECC) and control logic.

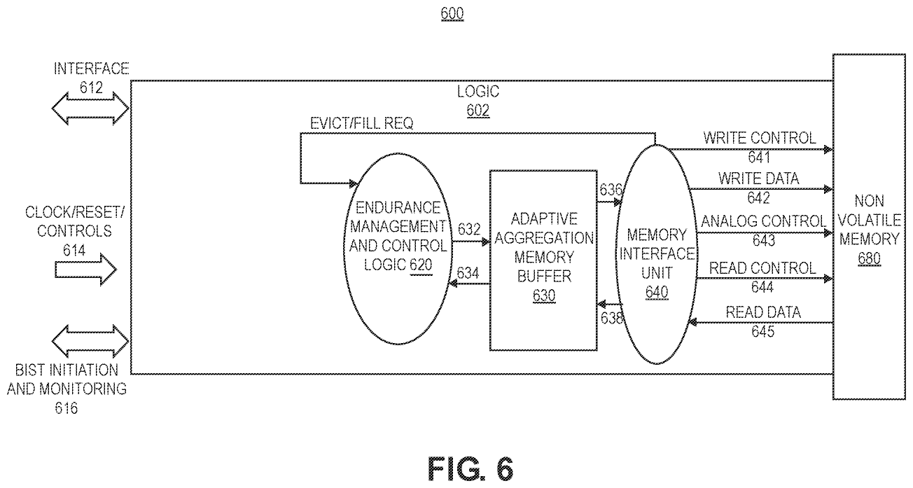

FIG. 6 illustrates a block diagram of an endurance management control logic (EMCL) of a memory subsystem in accordance with one embodiment. The memory subsystem 600 (e.g., AI subsystem, memory circuitry 600) includes multiple interface options includes an interface 612 (e.g., parallel interface, AXI interface, UPI interface, advanced interface bus (AIB), etc.), a clock, reset, and controls interface 614, and a Built-In Self Test (BIST) initiation and monitoring interface 616.

The memory subsystem 600 also includes logic 602 that includes an endurance management and control logic (EMCL) 620, an adaptive aggregation memory buffer 630, and a memory interface unit 640. The logic 602 and 620 can be hardware logic, logic circuitry, or program logic for performing instructions.

The memory array 680 can be any type of Non-volatile memory (e.g., embedded flash memory, magnetic RAM (MRAM) such as spin-transfer-torque (STT) memory cells, spin-orbit-torque (SOT) memory cells, resistive RAM (RRAM, ReRAM), phase-change RAM (PCRAM), carbon nanotube memory cells, etc.) or Ferroelectric RAM (FeRAM) for applications ranging from non-volatile RAM to low-power, high-density SRAM.

The adaptive aggregation memory buffer 630 operates in tandem with the memory subsystem 600 and can be managed with the logic 620. The adaptive aggregation memory buffer 630 can be modulated based on memory request type, usage pattern for an application, or operating condition. The adaptive aggregation memory buffer 630 is optimized for power, performance, or endurance. In one example, the adaptive aggregation memory buffer 630 has selective power down modes for power and/or endurance optimization. To optimize performance, all blocks of the adaptive aggregation memory buffer 630 are powered ON. To optimize power and endurance, some of the blocks can be powered OFF. In another example, variable clock rates can be adjusted for power versus performance optimization. In another example, configurable settings (e.g., first mode optimized for writing large amount of data, second mode optimized for writing small amount of data, third mode optimized for high speed writing, fourth mode optimized for low speed writing) of the adaptive aggregation memory buffer 630 can be adjusted for endurance versus speed optimization. These configurable settings can be automatically saved in the memory array 680.

In one embodiment, the logic 620 receives input from the interface 612, clock, reset, and controls 614, or BIST initiation and monitoring 616. The logic 620 processes the input and generates output such as configuration settings 632 to be sent to the buffer 630 and receives output 634 from the buffer 630. The buffer 630 sends output 636 to the memory interface unit 640, which then sends this output such as write control 641, write data 642, analog control 643, or read control 644 to the memory 680. Read data 645 can be sent from the memory 680 to the memory interface unit 640 to the buffer 630 as read data 638 and then the read data 634 is sent to the logic 620. The memory interface unit 640 can also send an evict/fill request 648 to the logic 620.

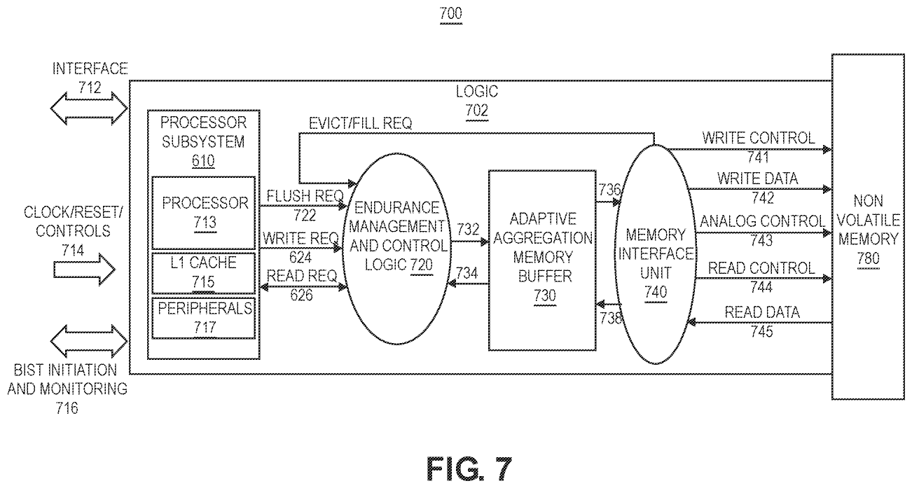

FIG. 7 illustrates a block diagram of an endurance management control logic (EMCL) and smart compute memory (e.g., SoC compute-in-memory) of a memory subsystem in accordance with one embodiment. The memory subsystem 700 (e.g., AI subsystem, memory circuitry 700) includes multiple interface options includes an interface 712 (e.g., parallel interface, AXI interface, UPI interface, advanced interface bus (AIB), etc.), a clock, reset, and controls interface 714, and a Built-In Self Test (BIST) initiation and monitoring interface 716.

The memory subsystem 700 also includes logic 702 that includes a processor subsystem 710, an endurance management and control logic (EMCL) 720, an adaptive aggregation memory buffer 730, and a memory interface unit 740. The logic 702 and 720 can be hardware logic, logic circuitry, or program logic for performing instructions.

The memory array 780 can be any type of Non-volatile memory (e.g., embedded flash memory, magnetic RAM (MRAM) such as spin-transfer-torque (STT) memory cells, spin-orbit-torque (SOT) memory cells, resistive RAM (RRAM, ReRAM), phase-change RAM (PCRAM), carbon nanotube memory cells, etc.) or Ferroelectric RAM (FeRAM) for applications ranging from non-volatile RAM to low-power, high-density SRAM.

The adaptive aggregation memory buffer 730 operates in tandem with the memory subsystem 700 and can be managed with the processor subsystem 710 that includes a processor 713, first level cache 715, and peripherals 717. The adaptive aggregation memory buffer 730 can be modulated based on memory request type, usage pattern for an application, or operating condition. The adaptive aggregation memory buffer 730 is optimized for power, performance, or endurance. In one example, the adaptive aggregation memory buffer 730 has selective power down modes for power and/or endurance optimization. To optimize performance, all blocks of the adaptive aggregation memory buffer 730 are powered ON. To optimize power and endurance, some of the blocks can be powered OFF. In another example, variable clock rates can be adjusted for power versus performance optimization. In another example, configurable settings (e.g., first mode optimized for writing large amount of data, second mode optimized for writing small amount of data, third mode optimized for high speed writing, fourth mode optimized for low speed writing) of the adaptive aggregation memory buffer 730 can be adjusted for endurance versus speed optimization. These configurable settings can be automatically saved in the memory array 780.

In one embodiment, the processor subsystem 710 receives input from the interface 712, clock, reset, and controls 714, or BIST initiation and monitoring 716. The processor 713 processes the input and generates output such as flush request 722, write request 724, and read request 726 that can be sent to the endurance management and control logic 720 for optimizing the endurance, performance, and power settings of the adaptive aggregation memory buffer 730. Logic 720 provides configuration settings 732 to the buffer 730 and receives output 734 from the buffer 730. The buffer 730 sends output 736 to the memory interface unit 740, which then sends this output such as write control 741, write data 742, analog control 743, or read control 744 to the memory 780. Read data 745 can be sent from the memory 780 to the memory interface unit 740 to the buffer 730 as read data 738 and then the read data 734 is sent to the logic 720 and then sent as a read request 726 to the processor subsystem 710. The memory interface unit 740 can also send an evict/fill request 748 to the logic 720.

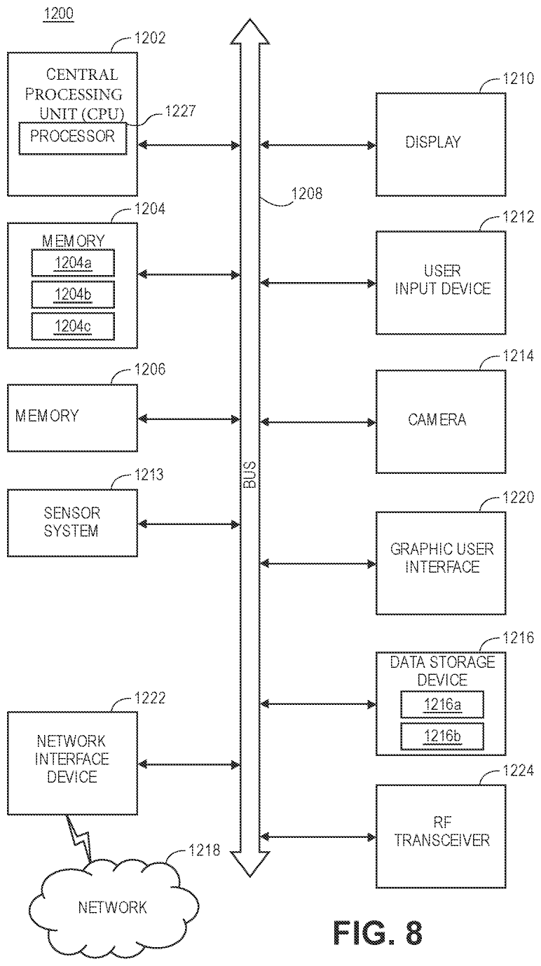

FIG. 8 is a diagram of a computer system (or computing system) including a data processing system according to an embodiment of the invention. Within the computer system 1200 is a set of instructions for causing the machine to perform any one or more of the methodologies discussed herein. In alternative embodiments, the machine may be connected (e.g., networked) to other machines in a LAN, an intranet, an extranet, or the Internet. The machine can operate in the capacity of a server or a client in a client-server network environment, or as a peer machine in a peer-to-peer (or distributed) network environment, the machine can also operate in the capacity of a web appliance, a server, a network router, switch or bridge, event producer, distributed node, centralized system, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

Data processing system 1202 (or CPU 1202), as disclosed above, includes a general purpose instruction-based processor 1227. The general purpose instruction-based processor may be one or more general purpose instruction-based processors or processing devices (e.g., microprocessor, central processing unit (CPU), or the like). More particularly, data processing system 1202 may be a complex instruction set computing (CISC) microprocessor, reduced instruction set computing (RISC) microprocessor, very long instruction word (VLIW) microprocessor, general purpose instruction-based processor implementing other instruction sets, or general purpose instruction-based processors implementing a combination of instruction sets.

The exemplary computer system 1200 (or wireless device 1200 such as mobile device, tablet device, smart watch, etc.) includes a data processing system 1202 (or CPU 1202), a main memory 1206 (e.g., read-only memory (ROM), flash memory, dynamic random access memory (DRAM) such as synchronous DRAM (SDRAM) or DRAM (RDRAM), etc.), a Non-volatile resistive RAM memory 1204 (e.g., resistive memory cells may include, but are not limited to, Magnetic RAM (MRAM) such as spin-transfer-torque (STT) memory cells, spin-orbit-torque (SOT) memory cells, resistor random access memory (ReRAM, RRAM), phase change RAM (PCRAM), carbon nanotube memory cells), etc.), embedded flash memory, or ferro-electric RAM (FeRAM) 1204 and a data storage device 1216 (e.g., a secondary memory unit in the form of a drive unit, which may include fixed or removable computer-readable storage medium), which communicate with each other via a bus 1208. The storage units and memory disclosed in computer system 1200 may be configured to implement the data storing mechanisms for performing the operations and steps discussed herein.

In one embodiment, the data storage device 1216 includes storage region 1216a and smart compute circuitry 1216b. The present design improves endurance, performance, and power consumption in Enterprise Storage Drives by utilizing the smart compute circuitry 1216b (e.g., integrated processor, microprocessor, microcontroller, etc.) to aggregate memory requests and perform some processing and computation operations native to the data storage device 1216 instead of sending data from the data storage device to interconnect to the bus 1208 to additional interconnect to the host system (e.g., CPU 1202) and then having the host system perform the operations or computations, and then send the processed data to the interconnect to the bus 1208 to additional interconnect to the data storage device 1216. In one example, database compare/matching operations are performed to determine whether a database should be stored in a data storage device for local processing or whether the database should be moved to a different location for processing.

Memory 1206 can store code and/or data for use by processor 1227. Memory 1206 includes a memory hierarchy that can be implemented using any combination of RAM (e.g., SRAM, DRAM, DDRAM), ROM, FLASH, magnetic and/or optical storage devices. Memory may also include a transmission medium for carrying information-bearing signals indicative of computer instructions or data (with or without a carrier wave upon which the signals are modulated).

The memory 1204 can be a memory subsystem (e.g., 100, 400, 500, 600, 700) as discussed herein. The memory 1204 can include any of the components of the memory subsystem such as I/O circuitry 1204a, smart compute memory circuitry 1204b, and resistive memory array 1204c.

Processor 1227 and smart compute memory circuitry 1204b execute various software components stored in memory to perform various functions for system 1200. In one embodiment, the software components include an operating system, compiler component, and communication module (or set of instructions). Furthermore, memory may store additional modules and data structures not described above.

Operating system includes various procedures, sets of instructions, software components and/or drivers for controlling and managing general system tasks and facilitates communication between various hardware and software components. A compiler is a computer program (or set of programs) that transform source code written in a programming language into another computer language (e.g., target language, object code). A communication module provides communication with other devices utilizing the network interface device 1222 or RF transceiver 1224. The network interface device 1222 is coupled with a network 1218 (e.g., local area network (LAN), wide area network (WAN)) to communicate with other devices.

The computer system 1200 may further include a network interface device 1222. The computer system 1200 also may include an optional display device 1210 (e.g., a liquid crystal display (LCD), LED, or a cathode ray tube (CRT)) connected to the computer system through a graphics port and graphics chipset, an optional input device 1212 (e.g., a keyboard, a mouse), a sensor system 1213, a camera 1214. In another example, the computer system is a wireless device 1200 (e.g., mobile device, tablet device, smart watch, etc.) that includes an optional Graphic User Interface (GUI) device 1220 (e.g., a touch-screen with input & output functionality).

The computer system 1200 may further include a RF transceiver 1224 that provides frequency shifting, converting received RF signals to baseband and converting baseband transmit signals to RF. In some descriptions a radio transceiver or RF transceiver may be understood to include other signal processing functionality such as modulation/demodulation, coding/decoding, interleaving/de-interleaving, spreading/dispreading, inverse fast Fourier transforming (IFFT)/fast Fourier transforming (FFT), cyclic prefix appending/removal, and other signal processing functions.

The data storage device 1216 may include a machine-readable storage medium (or more specifically a computer-readable storage medium) on which is stored one or more sets of instructions embodying any one or more of the methodologies or functions described herein. Disclosed data storing mechanism may be implemented, completely or at least partially, within the main memory 1206 and/or within the data processing system 1202 by the computer system 1200, the main memory 1206 and the data processing system 1202 also constituting machine-readable storage media.

In one example, the computer system 1200 is an autonomous vehicle that may be connected (e.g., networked) to other machines or other autonomous vehicles in a LAN, WAN, or any network. The autonomous vehicle can be a distributed system that includes many computers networked within the vehicle. The autonomous vehicle can operate in the capacity of a server or a client in a client-server network environment, or as a peer machine in a peer-to-peer (or distributed) network environment. The storage units disclosed in computer system 1200 may be configured to implement data storing mechanisms for performing the operations of autonomous vehicles.

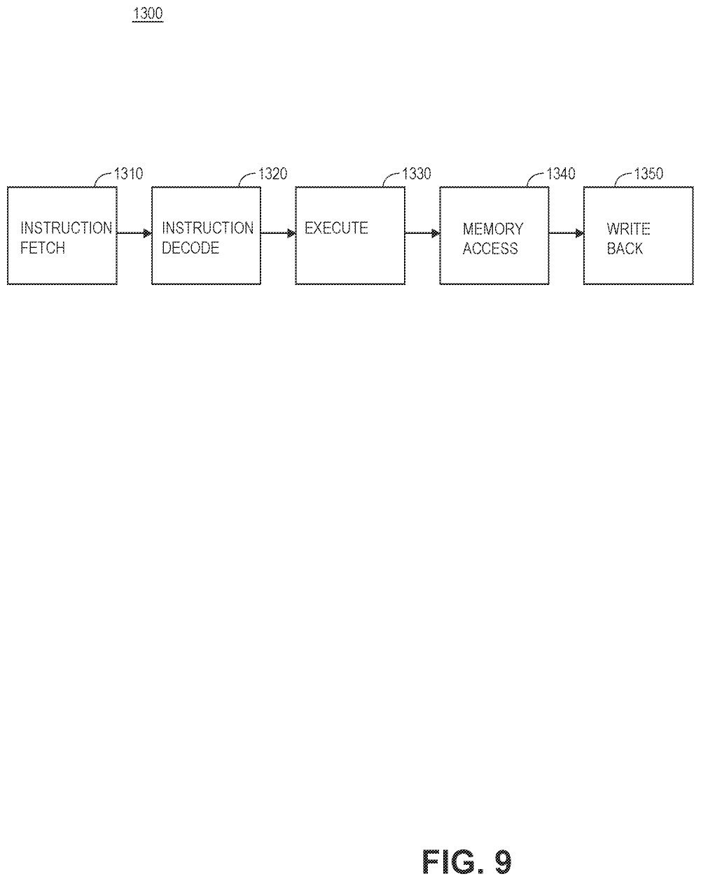

FIG. 9 illustrates a flow diagram 1300 of operational stages of a processor (e.g., RISC, smart compute circuitry, integrated processor) in accordance with one embodiment. In one example, at stage 1310, the processor initially fetches an instruction from memory (e.g., memory array 180, 480, 580, 680, 780, memory 1204, memory 1206). At stage 1320, the instruction is then decoded to determine what action may then be performed. Based on the instruction the processor fetches, if required, data from memory or an I/O module.

At stage 1330, the instruction is then executed which may require performing arithmetic or logical operations on the data. In addition to execution, the processor also supervises and controls I/O devices or I/O modules (e.g., I/O circuitry 110, input device 1212, GUI 1220). If there is any request from I/O devices or I/O modules, called interrupt, the processor suspends execution of the current programs and transfers control to an interrupt handling program. The results of an execution may require a memory access at stage 1340 to transfer data to the memory, I/O device, or an I/O Module. At stage 1350, the processor performs a write back policy with the data being written to registers of the processor.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The bus may also link various other circuits such as timing sources, peripherals, voltage regulators, power management circuits, and the like, which are well known in the art, and therefore, will not be described any further.

Any of the following examples can be combined into a single embodiment or these examples can be separate embodiments. In one example of an embodiment, a memory subsystem comprising: a resistive memory array; an adaptive aggregation memory buffer having configurable settings for optimizing endurance, power, or performance of the memory subsystem; an endurance management and control logic (EMCL) coupled to the adaptive aggregation memory buffer; and an optional integrated processor coupled to the EMCL. At least one of the integrated processor and EMCL is configured to determine whether localized memory requests to a particular memory region during a time window can be aggregated into an aggregate memory request and optimize memory settings, and to cause the aggregate memory request and memory settings to be sent to the resistive memory array to optimize parameters including memory performance and memory endurance.

In another example, the resistive memory array comprises non-volatile random access memory (RAM) including one or more of Magnetic RAM (MRAM), resistor random access memory (ReRAM, RRAM), phase change RAM (PCRAM), and/or carbon nanotube memory cells. Alternatively, the resistive memory array can be replaced with ferro-electric RAM (FeRAM) or embedded flash memory.

In another example, the integrated processor is configured with programmable memory management and control to optimize parameters including memory performance and memory endurance.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A memory subsystem comprising:
a resistive memory array;
an adaptive aggregation memory buffer having configurable settings for optimizing endurance, power, or performance of the memory subsystem;
an endurance management and control logic (EMCL) coupled to the adaptive aggregation memory buffer; and
an integrated processor coupled to the EMCL, wherein at least one of the integrated processor and EMCL is configured to determine whether memory requests to a particular memory region during a time window can be aggregated into an aggregate memory request and to optimize memory settings, and to cause the aggregate memory request and memory settings to be sent to the resistive memory array to optimize parameters including memory performance and memory endurance.

2. The memory subsystem of claim 1, wherein the EMCL is configured to receive input from the integrated processor and to determine a configurable memory setting of the adaptive aggregation memory buffer based on a memory request type, a usage pattern of an application, or an operating condition.

3. The memory subsystem of claim 1, wherein the adaptive aggregation memory buffer, EMCL, and integrated processor are integrated with the resistive memory array.

4. The memory subsystem of claim 1, wherein the adaptive aggregation memory buffer, EMCL, and integrated processor are directly adjacent to the resistive memory array.

5. The memory subsystem of claim 1, wherein the memory subsystem comprises a system on chip (SoC) compute-in-memory.

6. The memory subsystem of claim 1, wherein the integrated processor is configured to preread cells of the resistive memory array that will be written by the aggregate memory request and to selectively write to the cells that will have a change in logic state based on the aggregate memory request without writing to cells having no change in logic state.

7. The memory subsystem of claim 1, wherein the resistive memory array comprises non-volatile random access memory (RAM) including one or more of magnetic RAM (MRAM), resistor random access memory, phase change RAM (PCRAM), voltage-controlled magnetic anisotropy (VCMA)-MRAM, or carbon nanotube memory cells.

8. A memory subsystem comprising:
an endurance management and control logic (EMCL);
an adaptive aggregation memory buffer coupled to the EMCL, wherein the adaptive aggregation memory buffer has configurable settings for optimizing endurance, power, or performance of the memory subsystem; and
a ferro-electric RAM (FeRAM) memory array or embedded flash memory coupled to the adaptive aggregation memory buffer, wherein the EMCL is configured to determine whether memory requests to one or more memory regions during a time window can be aggregated into an aggregate memory request, and to cause the aggregate memory request to be sent to the FeRAM memory array or the embedded flash memory to optimize parameters including memory performance and memory endurance.

9. The memory subsystem of claim 8, wherein the EMCL is configured to determine a configurable setting of the adaptive aggregation memory buffer based on a memory request type, a usage pattern of an application, or an operating condition.

10. The memory subsystem of claim 9, wherein the adaptive aggregation memory buffer has selective power down modes for power and endurance optimizations.

11. The memory subsystem of claim 8, wherein the adaptive aggregation memory buffer and EMCL are integrated with the FeRAM memory array or embedded flash memory.

12. The memory subsystem of claim 9, wherein the adaptive aggregation memory buffer and EMCL are directly adjacent to the FeRAM memory array or embedded flash memory.

13. The memory subsystem of claim 8, wherein the memory subsystem comprises a system on chip (SoC) compute-in-memory.

14. The memory subsystem of claim 8, wherein the EMCL is configured to cause a preread of cells of the FeRAM memory array or embedded flash memory that will be written by the aggregate memory request and to selectively write to the cells that will have a change in logic state based on the aggregate memory request without writing to cells having no change in logic state.

15. A computer-implemented method for operating a memory subsystem, the computer-implementing method comprises:
receiving memory requests, with an endurance management and control logic (EMCL), for a non-volatile memory array of the memory subsystem including a non-volatile resistive memory, embedded flash memory, or Ferroelectric RAM (FeRAM);
storing the memory requests in an adaptive aggregation memory buffer of the memory subsystem; and
determining whether the memory requests to one or more memory regions during a time window can be aggregated into an aggregated memory request to improve endurance, performance, and/or power consumption before sending the memory requests to the non-volatile memory array.

16. The computer-implemented method of claim 15, further comprising:
aggregating with the EMCL memory requests including write operations aggregated based on time and memory space localization or read operations aggregated based on time and memory space localization into the aggregate memory request or a reduced number of memory requests.

17. The computer-implemented method of claim 15, wherein write operations are aggregated into a single write operation for a temporal and spatial locality within a range of memory addresses of the non-volatile memory array.

18. The computer-implemented method of claim 16, further comprising:
at periodic intervals or whenever the adaptive aggregation memory buffer of the memory subsystem is a threshold amount full, performing a preread of cells of the non-volatile memory array that will be written to based on the aggregate memory request.

19. The computer-implemented method of claim 18, further comprising:
processing the aggregate memory request selectively for each cell of the non-volatile memory array that will have a change in logic state.

20. The computer-implemented method of claim 19, wherein the change in logic state comprises a change in resistance state when the non-volatile memory includes a resistive memory array.
